(19) United States
(12) Patent Application Publication
(10) Pub. No.: US 2026/0181965 A1
(43) Pub. Date: Jun. 25, 2026

(54) CHARGE STORAGE TYPE TUNNELING TRANSISTOR DEVICE, MANUFACTURING METHOD THEREOF, AND BOOLEAN LOGIC OPERATION METHOD

(71) Applicant: SEOUL NATIONAL UNIVERSITY R&DB FOUNDATION, Seoul (KR)

(72) Inventors: Woo Young CHOI, Seoul (KR); Chang Heon PARK, Sejong-si (KR); Jae Seung WOO, Seoul (KR); Jang Woo LEE, Anyang-si, Gyeonggi-do (KR)

(73) Assignee: SEOUL NATIONAL UNIVERSITY R&DB FOUNDATION, Seoul (KR)

(21) Appl. No.: 18/836,279

(22) PCT Filed: Apr. 3, 2024
(86) PCT No.: PCT/KR2024/004316

§ 371 Date: Aug. 6, 2024

(30) Foreign Application Priority Data
Apr. 5, 2023 (KR) 10-2023-0044785
Apr. 1, 2024 (KR) 10-2024-0044371

(51) Int. Cl. H10D 30/69; G11C 16/04; H10B 43/30; H10D 30/01; H10D 64/01

(52) U.S. Cl. CPC H10D 30/697; G11C 16/0475; H10B 43/30; H10D 30/0413; H10D 64/037; G11C 2216/12

(57) ABSTRACT

A charge storage type tunneling transistor device, includes a semiconductor substrate, a gate formed on the semiconductor substrate, a source region and a drain region spaced apart from each other via a channel region that is formed under the gate, a dielectric layer formed between the gate and the channel region, and first and second charge storage layers buried in the dielectric layer to be spaced apart from each other, and independently storing charge.

### CROSS-REFERENCE TO PRIOR APPLICATIONS

This application is a National Stage Patent Application of PCT International Application No. PCT/KR2024/004316 (filed on Apr. 3, 2024), which claims priority to Korean Patent Application Nos. 10-2023-0044785 (filed on Apr. 5, 2023) and 10-2024-0044371 (filed on Apr. 1, 2024), which are all hereby incorporated by reference in their entirety.

### BACKGROUND

The present disclosure relates to a charge storage type tunneling transistor technology, and more specifically, to a charge storage type tunneling transistor device specialized for Process In Memory (PIM) capable of Boolean logic operation based on a tunneling field effect transistor that has an advantage in ultra-power operation, a manufacturing method thereof, and a Boolean logic operation method.

As global demand for intelligent semiconductors and portable electronic devices increases, the need for low-power devices is also increasing rapidly. Meanwhile, in the case of the existing von Neumann structure, as the amount of operational data increases exponentially, energy consumption due to data movement between a processing unit and a memory unit is becoming serious problems.

Until now, attempts have been made in the field of semiconductor technology to improve operation speed and the degree of integration by reducing the size of devices. However, additional device scaling is hindered by problems such as increased processing costs, increased leakage current due to short-channel effect, and reduced gate control. Recently, with the declaration of the abolition of Moore's Law, interests in the field of semiconductor technology have shifted from improving operation speed and integration degree to changing a basic structure for data operation or implementing low-power/high-energy-efficiency devices. An existing operation method using the von Neumann structure requires a data transfer process between the processing unit and the memory unit. However, when a large amount of data is required for operation, it has a disadvantage that energy consumed in this process is very large. Therefore, there is a need for technology to implement operation within a memory without energy consumption due to data movement between the processing unit and the memory unit.

The present disclosure proposes a charge storage type tunneling transistor device that can dramatically reduce a data movement between a processing unit and a memory unit when performing the Boolean logic operation. The charge storage type tunneling transistor device proposed by the present disclosure will play a key role in securing new memory/non-memory technology with low power/high energy efficiency suitable for the big data era that requires mass data processing, and is expected to contribute to preoccupying and leading a next-generation low power/high energy efficiency memory/non-memory market in the future.

### PRIOR ART DOCUMENT

Korean Patent No. 10-2273935 (2021 Jun. 30)

### SUMMARY

One embodiment of the present disclosure is to provide a charge storage type tunneling transistor device specialized for ultra-low power PIM capable of Boolean logic operation through a charge storage type tunneling transistor that is highly compatible with an existing silicon CMOS process, a manufacturing method thereof, and a Boolean logic operation method.

Among embodiments, a charge storage type tunneling transistor device includes a semiconductor substrate, a gate formed on the semiconductor substrate, a source region and a drain region spaced apart from each other via a channel region that is formed under the gate, a dielectric layer formed between the gate and the channel region, and first and second charge storage layers buried in the dielectric layer to be spaced apart from each other, and independently storing charge.

The dielectric layer may be primarily formed between the gate and the channel region, and at least portion thereof may overlap the channel region.

The dielectric layer may be secondarily formed on the source region and the drain region.

The dielectric layer may be formed of a first dielectric constant dielectric film material or a second dielectric constant dielectric film material having different dielectric constants.

The first dielectric constant dielectric film material may include one of silicon oxide (SiO₂) and silicon oxynitride (SiON).

The second dielectric constant dielectric film material may include one of strontium oxide (SrO), aluminum oxide (Al₂O₃), magnesium oxide (MgO), scandium oxide (Sc₂O₃), gadolinum oxide (Gd₂O₃), yttrium oxide (Y₂O₃), samarium oxide (Sm₂O₃), hafnium oxide (HfO₂), zirconium oxide (ZrO₂), titanium oxide (TiO₂), tantalum oxide (Ta₂O₅), barium oxide (BaO), and bismuth oxide (Bi₂O₃).

The first and second charge storage layers may independently or simultaneously control the storage of the charge through selective program or erase operation.

The first and second charge storage layers may selectively or simultaneously perform the program or erase operation by adjusting a threshold voltage (Vₜₕ) that is a gate voltage when a tunneling current above a certain level flows between the source region and the channel region or an ambipolar voltage (V_{amb}) that is a gate voltage when a tunneling current above a certain level flows between the drain region and the channel region.

The first and second charge storage layers may be formed of a hetero gate dielectric, and be made of the same material.

The first and second charge storage layers may be formed of polysilicon or a material selected from Si₃N₄, HfO₂, Al₂O₃, and combinations thereof.

The first and second charge storage layers may be formed on top of the secondarily formed dielectric layer in the source region and the drain region, respectively.

Among embodiments, a method of manufacturing a charge storage type tunneling transistor device includes forming a dielectric layer and a gate layer over a semiconductor substrate, forming a source region, a drain region, and a channel region within the semiconductor substrate, forming an undercut-shaped space on both sides on a bottom of the gate layer by etching both sides of the dielectric layer, forming an oxide film on an entire surface including the dielectric layer through an oxidation process and forming a charge storage layer along the entire surface to fill the undercut-shaped space, and forming first and second charge storage layers buried in the dielectric layer to be spaced apart from each other by etching the oxide film and the charge storage layer.

The dielectric layer may be formed of silicon oxide (SiO₂), and the space may be created by performing an HF vapor etch process.

The first and second charge storage layers may independently store charge by selectively or simultaneously performing program and erase operations.

Among embodiments, a Boolean logic operation method of a charge storage type tunneling transistor device includes step 1 of setting first and second charge storage layers to an initial state, the first and second charge storage layers being buried in a dielectric layer formed between a gate and a channel region to be spaced apart from each other and independently storing charge, step 2 of performing a Boolean logic operation by performing selective program or erase operation, and step 3 of performing a read operation on a result of the Boolean logic operation.

The step 1 may initialize the threshold voltage (Vₜₕ) and ambipolar voltage (V_{amb}) to an arbitrary value.

The step 2 may include adjusting a voltage level of the threshold voltage (Vₜₕ) by performing program or erase operation of the first charge storage layer, and adjusting a voltage level of the ambipolar voltage (V_{amb}) by performing program and erase operation of the second charge storage layer, wherein the voltage level adjustment of the threshold voltage (Vₜₕ) and the voltage level adjustment of the ambipolar voltage (V_{amb}) may be independently performed.

The step 2 may include performing program or erase operation on the first charge storage layer through BBHE (Band-to-band tunneling induced hot-electron injection) or FN (Fowler Nordheim) tunneling.

The step 2 may include performing program or erase operation on the second charge storage layer through BBHH (Band-to-band tunneling induced hot-hole injection) or DHE (drain hot-electron injection).

The step 3 may include performing read operation of the first charge storage layer or the second charge storage layer by adjusting a voltage level of gate voltage (V_{G}), and comparing a current level of drain current (I_{D}) during the read operation with a reference level to determine a result of the Boolean logic operation.

The disclosed technology can have the following effects. However, it is not intended to mean that a specific embodiment should include all of the following effects or only the following effects, and the scope of the disclosed technology should not be understood as being limited thereby.

A charge storage type tunneling transistor device, a manufacturing method thereof, and a Boolean logic operation method according to one embodiment of the present disclosure provide the effect of high compatibility with an existing memory process, by using a tunneling transistor with low power/high energy efficiency characteristics. Further, the present disclosure enables the implementation of an energy-saving semiconductor system that requires a low leakage current and a field that requires mass data processing. Furthermore, it can be applied to a system semiconductor used in a portable electronic device using a battery that requires low standby power, and can achieve the effect of dramatically reducing data movement between a memory unit and a processing unit.

### BRIEF DESCRIPTION OF THE DRAWINGS

FIG. 1 is a diagram explaining a Von Neumann structure and a method of operating a process-in memory (PIM) technology.

FIG. 2 is a sectional view illustrating a charge storage type tunneling transistor device according to an embodiment of the present disclosure.

FIG. 3 is a graph illustrating changes in drain current and gate voltage according to the operation of the charge storage type tunneling transistor device of the present disclosure.

FIG. 4 is a graph illustrating the result of simulating a selective program operation of the charge storage type tunneling transistor device according to the present disclosure.

FIG. 5 is a graph illustrating the result of simulating a selective erase operation of the charge storage type tunneling transistor device according to the present disclosure.

FIG. 6 is a graph showing the intensity distribution of an electric field of the charge storage type tunneling transistor device of the present disclosure.

FIG. 7 is a diagram explaining an embodiment of the Boolean logic operation process of the charge storage type tunneling transistor device according to the present disclosure.

FIGS. 8 to 10 are diagrams explaining steps of the Boolean logic operation using the charge storage type tunneling transistor device of the present disclosure.

FIG. 11 is a graph showing a simulation result of AND operation.

FIGS. 12A to 12E are diagrams illustrating a method of manufacturing a charge storage type tunneling transistor device according to an embodiment of the present disclosure.

### DETAILED DESCRIPTION

The description of the present disclosure is only an example for structural or functional explanation, and the scope of the present disclosure should not be construed as limited by the embodiments described herein. In other words, the embodiments can be modified in various ways and can have various forms, and the scope of the present disclosure should be understood to include equivalents that can realize the technical idea. In addition, the purpose or effect presented in the present disclosure does not mean that a specific embodiment should include all or only such effects, so the scope of the present disclosure should not be understood as limited thereby.

Meanwhile, the meaning of the terms described in the present specification should be understood as follows.

The terms such as “first”, “second”, etc. are intended to distinguish one component from another component, and the scope of the present disclosure should not be limited by these terms. For example, a first component may be named as a second component, and similarly, the second component may also be named as the first component.

When it is described that a component is “connected” to another component, it should be understood that one component may be directly connected to another component, but that other components may also exist between them. On the other hand, when it is described that a component is “directly connected” to another component, it should be understood that there is no other component between them. Meanwhile, other expressions that describe the relationship between components, such as “between” and “immediately between” or “neighboring” and “directly neighboring” should be interpreted similarly.

Singular expressions should be understood to include plural expressions unless the context clearly indicates otherwise, and terms such as “comprise or include” or “have” are intended to specify the existence of implemented features, numbers, steps, operations, components, parts, or combinations thereof, but should be understood as not precluding the possibility of the existence or addition of one or more other features, numbers, steps, operations, components, parts, or combinations thereof.

For each step, identification codes (e.g., a, b, c, etc.) are used for convenience of description. The identification codes do not explain the order of the steps, and the steps may be performed in a different order than the specified order unless the context clearly indicates otherwise. That is, the steps may occur in the same order as specified, and may be performed substantially simultaneously or in the reverse order.

Unless otherwise defined, all terms used herein have the same meaning as commonly understood by one of ordinary skill in the art to which the present disclosure belongs. It will be further understood that terms used herein should be interpreted as having a meaning that is consistent with their meaning in the context of this specification and the relevant art and will not be interpreted in an idealized or overly formal sense unless expressly so defined herein

Hereinafter, preferred embodiments of the present disclosure will be described in detail with reference to the accompanying drawings. The same reference numerals are used throughout the drawings to designate the same components, and duplicated description of the same components will be omitted.

The field of artificial intelligence (AI) technology is used in many application fields and is being explosively developed. Attempts to solve various difficult problems through AI are continuing. In order to implement more accurate and precise artificial intelligence, a large amount of data operation is increasingly required. In contrast, existing processor technology for operation processing is currently holding back the implementation of high-performance/low-power AI due to the limitations of Moorer's law and structural problems with the von Neumann architecture. Therefore, a new computing system optimized for the implementation of AI is urgently needed, and companies and countries possessing the technology are likely to lead the AI technology and semiconductor markets.

Accordingly, the present disclosure proposes a charge storage type tunneling transistor device that can implement high energy efficiency operation by significantly reducing data movement between a processing unit and a memory unit, thereby gaining competitive advantages in an energy saving field, which will grow rapidly in the future, and seeks to contribute to leading overall next-generation high-energy efficiency memory/non-memory semiconductor markets.

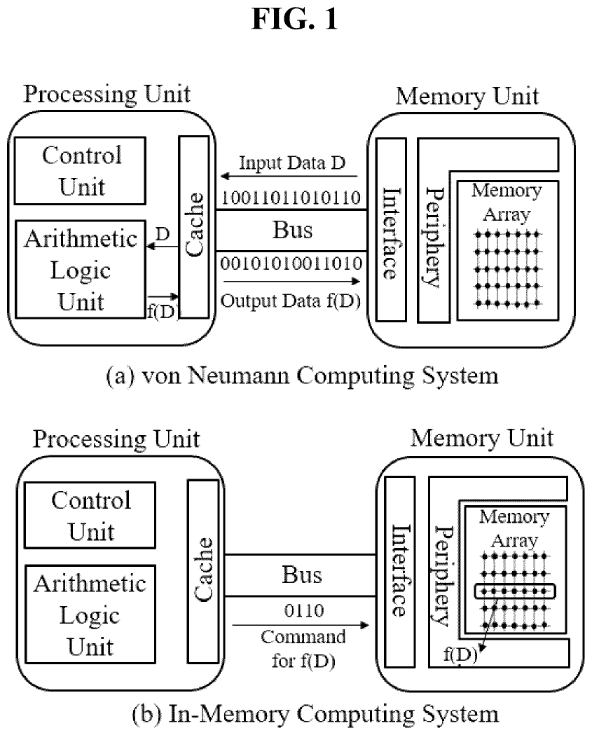

FIG. 1 is a diagram explaining a Von Neumann structure and a method of operating a process-in memory (PIM) technology. FIG. 1(a) shows the von Neumann structure, and FIG. 1(b) shows the operation method of the PIM technology.

The von Neumann structure is a structure in which a memory unit and a processing unit are physically separated, and data movement through a bus is essential for data processing. This means that as the amount of data to be processed increases, time consumption and energy loss due to data movement between the processing unit and the memory unit gradually increase. Therefore, in a field requiring mass data processing, such as the AI field, the von Neumann structure is inefficient in terms of operation time and energy consumption. In order to solve this problem, several attempts are continuously made to realize new beyond von Neumann computing technology. Thus, the present disclosure proposes the manufacturing and operation principle of a charge storage type tunneling transistor device specialized for ultra-low power PIM capable of Boolean logic operation through the charge storage type tunneling transistor that is highly compatible with the silicon CMOS process.

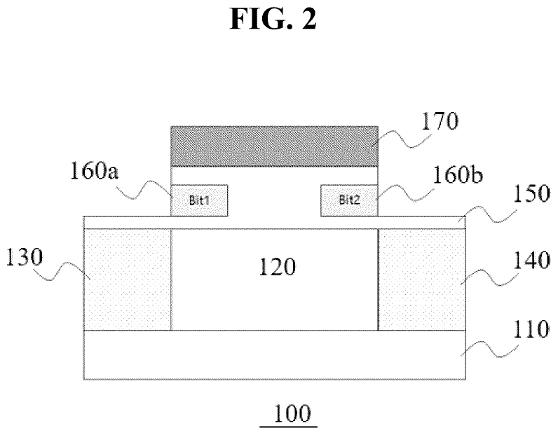

FIG. 2 is a sectional view illustrating a charge storage type tunneling transistor device according to an embodiment of the present disclosure.

Referring to FIG. 2, the charge storage type tunneling transistor device 100 includes a semiconductor substrate 110, a source region 130, a drain region 140, a channel region 120, a dielectric layer 150, and a gate 170.

The semiconductor substrate 110 may be formed through a bulk Si wafer or formed through a Silicon On Insulator (SOI). The semiconductor substrate 110 may be formed of a buried oxide (BOX) at the bottom of the SOI and a silicon substrate. Here, the SOI may correspond to a substrate of a structure with an insulating layer formed between silicon single crystal layers. The buried oxide is an oxide layer used as an insulating film, not only serves as an electrical insulator but also corresponds to oxide used to isolate devices in the process of manufacturing an integrated circuit, and serves as a diffusion barrier for regions other than a specific region in the process of doping impurities into the specific region on the SOI. Hereinafter, the semiconductor substrate 110 is not necessarily limited thereto.

The gate 170 is formed over the semiconductor substrate 110. The channel region 120 is formed under the gate 170. The channel region 120 may be formed between the source region 130 and the drain region 140 in the semiconductor substrate 110.

The source region 130 and the drain region 140 are formed in the semiconductor substrate 110 to be spaced apart from each other via the channel region 120. The source region 130 and the drain region 140 may be formed by doping different types of impurities. For example, the source region 130 may be formed as a P+ region, while the drain region 140 may be formed as an N+ region. Here, N-type impurities may include at least one of arsenic (As), phosphorus (P), bismuth (Bi), and antimony (Sb), while P-type impurities may include at least one of aluminum (Al), boron (B), indium (In), and gallium (Ga).

The dielectric layer 150 is formed between the gate 170 and the channel region 120. The dielectric layer 150 may be formed to contact the source region 130, the channel region 120, and the drain region 140 on the semiconductor substrate 110. To be more specific, the dielectric layer 150 is primarily formed between the gate 170 and the channel region 120, and at least a portion thereof may overlap the channel region 120. The dielectric layer 150 may be secondarily formed on the source region 130 and the drain region 140. First and second charge storage layers 160a and 160b may be locally formed in the dielectric layer 150 to be adjacent to the source region 130 and the drain region 140.

The dielectric layer 150 may be formed of a first dielectric constant dielectric film material or a second dielectric constant dielectric film material having different dielectric constants. Here, a first dielectric constant dielectric film may correspond to a low dielectric constant (Low-k) film with a lower dielectric constant than a second dielectric constant dielectric film, while the second dielectric constant dielectric film may correspond to a high dielectric constant (High-k) film.

The first dielectric constant dielectric film material may include one of silicon oxide (SiO₂) and silicon oxynitride (SiON). The second dielectric constant dielectric film material may include one of strontium oxide (SrO), aluminum oxide (Al₂O₃), magnesium oxide (MgO), scandium oxide (Sc₂O₃), gadolinum oxide (Gd₂O₃), yttrium oxide (Y₂O₃), samarium oxide (Sm₂O₃), hafnium oxide (HfO₂), zirconium oxide (ZrO₂), titanium oxide (TiO₂), tantalum oxide (Ta₂O₅), barium oxide (BaO), and bismuth oxide (Bi₂O₃).

The first and second charge storage layers 160a and 160b may be buried in the dielectric layer 150 to be spaced apart from each other, and may store charges independently of each other. The first and second charge storage layers 160a and 160b may be formed on top of the secondarily formed dielectric layer 150 in the source region 130 and the drain region 140, respectively. The first and second charge storage layers 160a and 160b are formed of a hetero gate dielectric, and may be formed of the same material. Here, the first and second charge storage layers 160a and 160b may be formed of polysilicon or a material selected from Si₃N₄, HfO₂, Al₂O₃, and combinations thereof.

The first and second charge storage layers 160a and 160b may independently control the storage of charges through selective program or erase operation. That is, the first and second charge storage layers 160a and 160b may selectively or simultaneously perform the program or erase operation by adjusting a threshold voltage that is a gate voltage when a tunneling current above a certain level flows between the source region 130 and the channel region 120 or an ambipolar voltage that is a gate voltage when a tunneling current above a certain level flows between the drain region 140 and the channel region 120.

The charge storage type tunneling transistor device 100 may perform memory operation of program, erase, and read through the first and second charge storage layers 160a and 160b to implement Boolean logic operation without a processing unit.

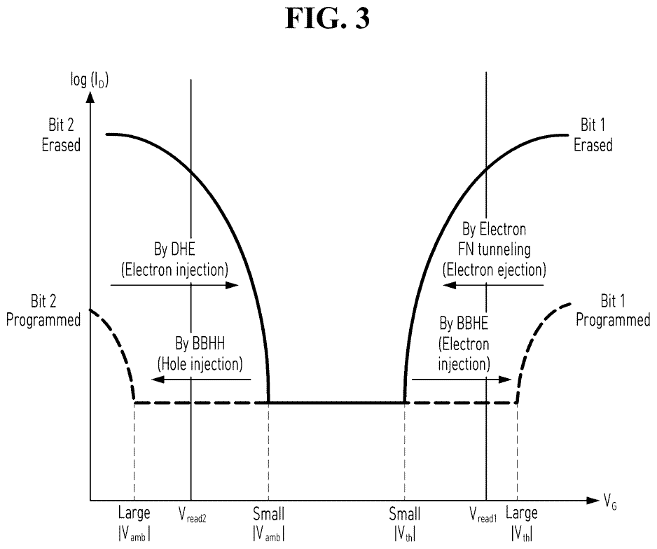

FIG. 3 is a graph illustrating changes in drain current and gate voltage according to the operation of the charge storage type tunneling transistor device of the present disclosure, and a graph illustrating changes in drain current I_{D} and gate voltage V_{G} according to the selective program and erase operation of the first and second charge storage layers.

Referring to FIG. 3, Bit1 and Bit2 correspond to the first and second charge storage layers 160a and 160b. The charge storage type tunneling transistor device 100 may perform the program or erase operation of Bit1 corresponding to the first charge storage layer 160a, by adjusting the voltage level of the threshold voltage Vₜₕ, which is a gate voltage when a tunneling current above a certain level flows between the source region 130 and the channel region 120, in a positive (+) or negative (−) direction. Further, the charge storage type tunneling transistor device 100 may perform the program or erase operation of Bit2 corresponding to the second charge storage layer 160b, by adjusting the voltage level of the ambipolar voltage V_{amb}, which is a gate voltage when a tunneling current above a certain level flows between the drain region 140 and the channel region 120, in a positive (+) or negative (−) direction.

The charge storage type tunneling transistor device 100 requires the process of programming and erasing on Bit1 and Bit2, which are the first and second charge storage layers 160a and 160b, in order to perform the Boolean logic operation. The charge storage type tunneling transistor device 100 has characteristics capable of selective program or erase operation. The selective program/erase operation refers to an operation that selectively adjusts only the threshold voltage Vₜₕ or the ambipolar voltage V_{amb}, and may be implemented by performing the program/erase operation on Bit1 or Bit2 corresponding to the first and second charge storage layers 160a and 160b through voltage conditions shown in Table 1 below. Table 1 below shows the operating conditions obtained by conducting TCAD simulation to develop and verify selective program and erase operating conditions of Bit1 and Bit2 in the charge storage type tunneling transistor device 100.

TABLE 1

| | Voltage [V] |
|---|---|
| Bit1 | V_{S} = 0 |
| Program | V_{G} = V_{G, Program} |
| | V_{D} = V_{D, Program} |
| Bit1 | V_{S} = V_{S, Program} |
| Erase | V_{G} = V_{G, Program2} |
| | V_{D} = 0 |
| Bit2 | V_{S} = 0 |
| Program | V_{G} = V_{G, Program2} |
| | V_{D} = V_{D, Program} |
| Bit2 | V_{S} = V_{S, Program} |
| Erase | V_{G} = V_{G, Program} |
| | V_{D} = 0 |

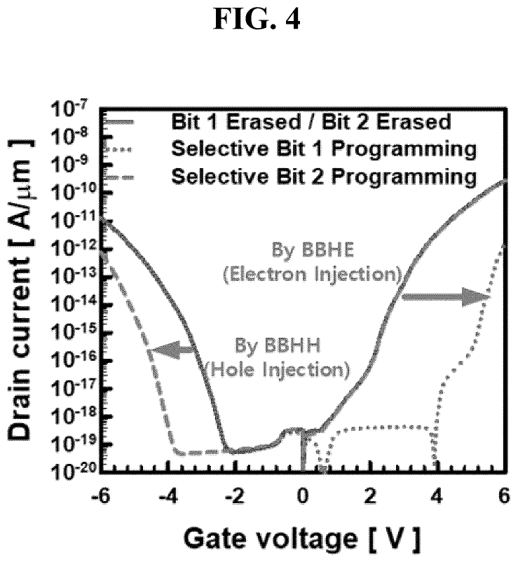

FIG. 4 is a graph illustrating the result of simulating the selective program operation of the tunneling transistor device according to the present disclosure.

Referring to FIG. 4, this is the result of simulating the program operation with both Bit1 and Bit2 erased to verify the selective program operation for each of Bit1 and Bit2, which are the first and second charge storage layers of the charge storage type tunneling transistor device of the present disclosure. Through simulation, it was confirmed that selective Bit1 program operation is possible through band-to-band tunneling induced hot-electron injection (BBHE). Further, it can be seen that selective Bit2 program operation is possible using band-to-band tunneling induced hot-hole injection (BBHH). Therefore, both the selective program operations may be independently implemented without affecting other Bits through the proposed voltage conditions.

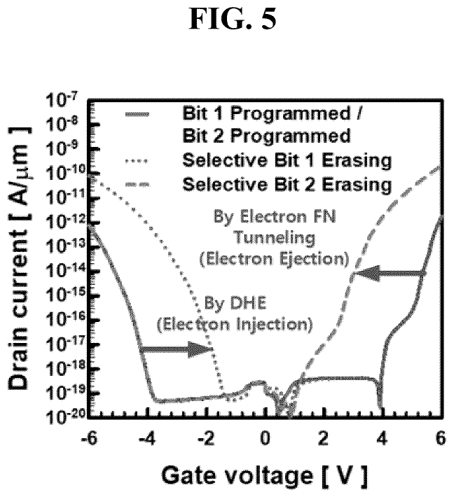

FIG. 5 is a graph illustrating the result of simulating the selective erase operation of the charge storage type tunneling transistor device according to the present disclosure.

Referring to FIG. 5, it was confirmed that the selective Bit1 erase operation is possible through Fowler Nordheim tunneling (FN tunneling), and the selective Bit2 erase operation is possible through drain hot-electron (DHE) injection using electrons supplied from a drain stage. However, the selective program/erase method is not limited to the above-described BBHE, BBHH, FN tunneling, and DHE, and may be implemented through various physical phenomena such as Poole-Frenkel emission.

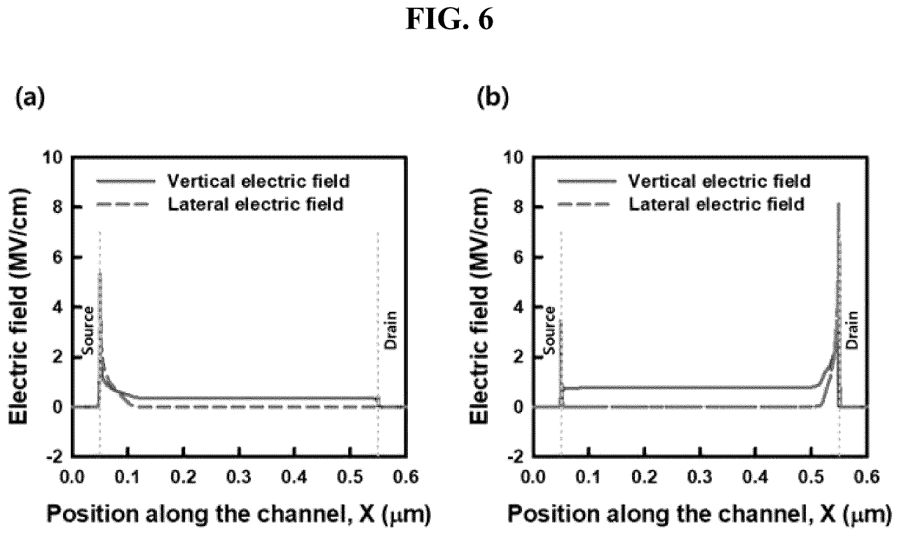

FIG. 6 is a graph showing the intensity distribution of the electric field of the charge storage type tunneling transistor device of the present disclosure, in which FIG. 6(a) illustrates the intensity distribution of the electric field of the charge storage type tunneling transistor device during Band-to-band tunneling induced hot-electron injection (BBHE), and FIG. 6(b) illustrates the intensity distribution of the electric field of the charge storage type tunneling transistor device during Band-to-band tunneling induced hot-hole injection (BBHH).

FIG. 6 shows the intensity distribution of the electric field of the charge storage type tunneling transistor device during the hot-carrier injection operation of the charge storage type tunneling transistor device according to the present disclosure. Since the tunneling transistor generates strong horizontal and vertical electric fields in the proximity of the source/channel or channel/drain tunnel junction during operation, efficient hot-carrier injection is possible using the electric fields. Further, since the threshold voltage and the ambipolar voltage of the charge storage type tunneling transistor device are mainly affected by the electric field applied to the source/channel or channel/drain tunnel junction, respectively, the fact that efficient hot-carrier injection is possible near the tunnel junction is advantageous in adjusting the threshold voltage and ambipolar voltage with low power/high energy efficiency.

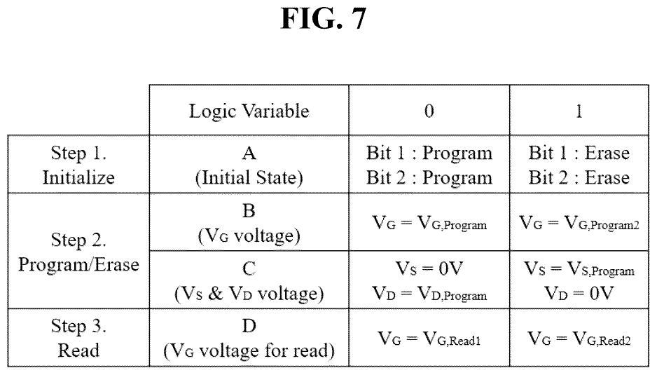

FIG. 7 is a diagram explaining an embodiment of the Boolean logic operation process of the charge storage type tunneling transistor device according to the present disclosure, and shows the Boolean logic operation steps of the device and the operating conditions of logic variables for each step.

Referring to FIG. 7, the charge storage type tunneling transistor device performs the Boolean logic operation by sequentially performing three steps, Initialization, Program/Erase, and Read.

First, the Initialization of step 1 corresponds to a logic variable A, the Program/Erase step of step 2 corresponds to logic variables B and C, and the Read step corresponds to a logic variable D. Here, the logic variable B is determined by the gate voltage V_{G}, and the logic variable C is determined by the source voltage V_{S} and the drain voltage V_{D}. Each logic variable may have a value of 0 to 1, or a variable p or q that is an input value of the Boolean logic operation. At this time, the variables p and q are used as input values for the Boolean logic operation, and a result value obtained by calculating p and q is read in the Read step.

Step 1 is the process of setting the first and second charge storage layers of the charge storage type tunneling transistor device to the initial state, and is present in two states in which both Bit1 and Bit2 are programmed and erased. A logic variable value corresponding to each state may be seen in FIG. 7.

Step 2 is the process of performing the Boolean logic operation by performing the selective program or erase operation. At this time, the logic variable is determined according to the voltage applied to the drain, gate, and source stages.

Step 3 is the process of performing the read operation on the result of the Boolean logic operation. In this step, the result value of the Boolean logic operation on the input variables p and q is read.

An example of the input value of the logic variable for performing the Boolean logic operation may be shown in Table 2. The Boolean logic operation is possible by inputting values shown in Table 2 into each logic variable A, B, C, or D. This is the result of verifying that AND operation through TCAD is possible.

TABLE 2

| | | | C | D |
|---|---|---|---|---|
| Boolean | A | B | (V_{S}&V_{D} | (V_{G} for Read |
| Logic | (Initialize) | (V_{G} bias) | bias) | operation) |
| 0 | 0 | p | 0 | q |
| 1 | 1 | p | 1 | q |
| p | 0 | 0 | 1 | p |
| q | q | 0 | 0 | 1 |
| p′ | 0 | 1 | 1 | p |
| q′ | 1 | 1 | 0 | q |
| p + q (OR) | 1 | 0 | p | q |
| p′ · q′ (NOR) | 0 | 1 | p′ | q |
| p · q (AND) | 0 | 0 | p | q |
| p′ + q′ (NAND) | 1 | 1 | p' | q |
| p · q + p′ · q′ | 1 | p′ | 0 | q |
| (XNOR) | | | | |
| p′ · q + p · q′ | 0 | p | 1 | q |
| (XOR) | | | | |

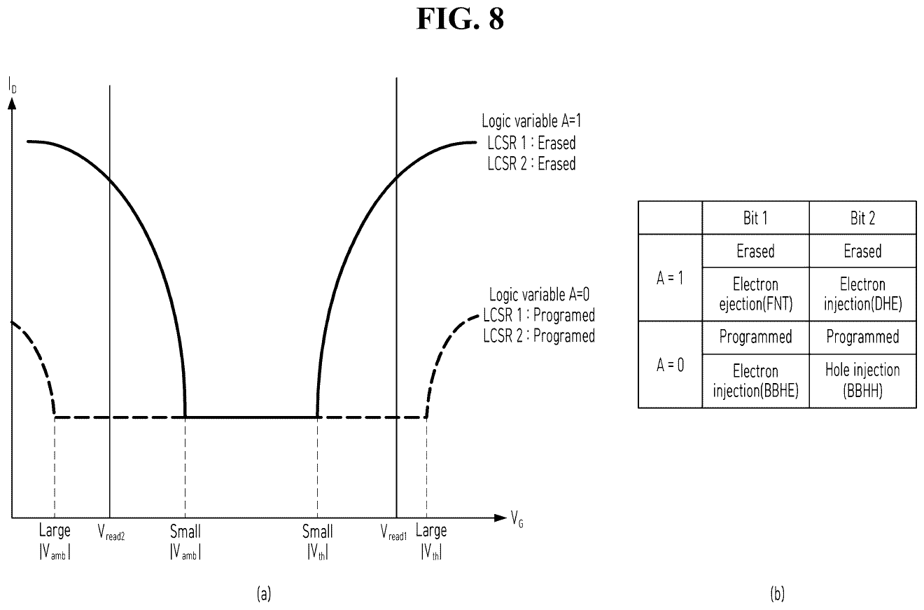

FIGS. 8 to 10 are diagrams explaining steps of the Boolean logic operation using the charge storage type tunneling transistor device of the present disclosure, in which (a) is a graph showing a drain current-gate voltage transfer function according to the logic variable value, and (b) is a Table showing a bias state according to the logic variable value.

First, FIG. 8 illustrates the Initialization step, which is step 1 of the Boolean logic operation. Step 1 sets the first and second charge storage layers to the initial state. Here, the first and second charge storage layers are buried in the dielectric layer formed between the gate and channel region of the charge storage type tunneling transistor device to be spaced apart from each other, and are configured to store charges independently of each other. Step 1 initializes the first and second charge storage layers with the proper threshold voltage Vₜₕ or the proper ambipolar voltage V_{amb}. Step 1 corresponds to the logic variable A of Table 2. FIG. 8(a) shows a relationship between drain current I_{D} and gate voltage V_{G} when the logic variable A is 0 or 1, respectively, and FIG. 8(b) shows the program/erase state of each Bit corresponding to the first and second charge storage layers according to the value of the logic variable A. Here, the logic variable A=1 represents the erase state for both Bit1 and Bit2, and A=0 represents the program state for both Bit1 and Bit2.

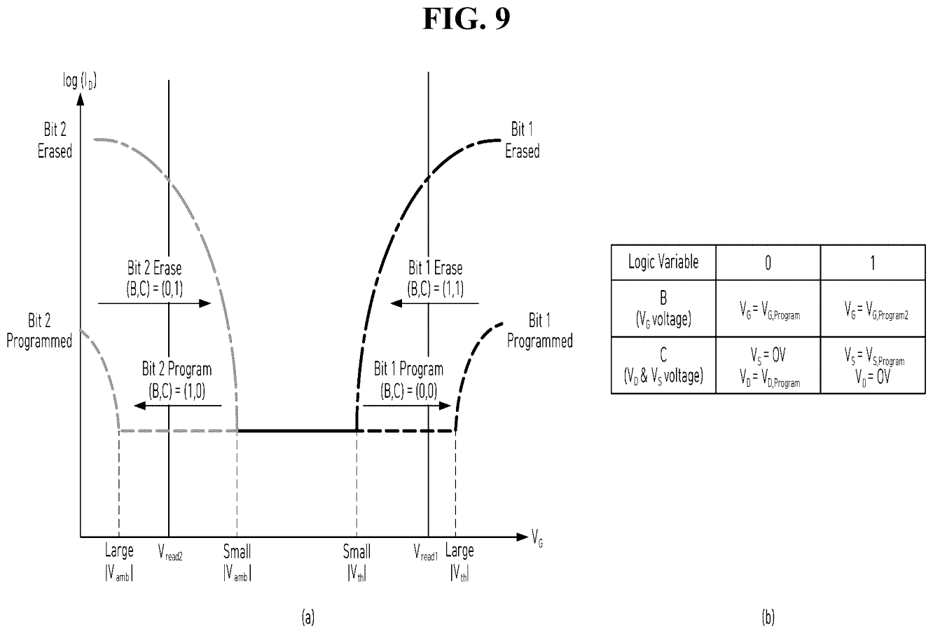

Next, FIG. 9 illustrates the Program/Erase step, which is step 2 of the Boolean logic operation, in which FIG. 9(a) shows changes in the threshold voltage Vₜₕ and the ambipolar voltage V_{amb} according to the combination of logic variables B and C, and FIG. 9(b) shows the bias state according to the values of logic variables B and C.

Step 2 performs the Boolean logic operation by performing the selective program or erase operation. In step 2, the voltage level of the threshold voltage Vₜₕ may be adjusted by performing the program or erase operation of the first charge storage layer. Further, step 2 may adjust the voltage level of the ambipolar voltage V_{amb} by performing the program or erase operation of the second charge storage layer. Step 2 may independently adjust the voltage level of the threshold voltage Vₜₕ and the voltage level of the ambipolar voltage V_{amb}. Step 2 allows a total four types of operations through programming or erasing on the first and second charge storage layers.

Step 2 performs the program or erase operation on the first charge storage layer through BBHE (Band-to-band tunneling induced hot-electron injection) or FN tunneling. BBHE (Band-to-band tunneling induced hot-electron injection) is a technology that injects and stores hot-electrons by applying voltage to the charge storage layer to induce a band-to-band tunneling phenomenon. For example, in step 2, the program operation is performed on Bit1 corresponding to the first charge storage layer through BBHE when both logic variables B and C are 0, and the erase operation is performed on Bit1 through FN tunneling when both logic variables B and C are 1.

Further, step 2 performs the program or erase operation on the second charge storage layer through BBHH (Band-to-band tunneling induced hot-hole injection) or DHE (drain hot-electron injection). For example, in step 2, the program operation is performed on Bit2 corresponding to the second charge storage layer through BBHH when the logic variables B and C are 1 and 0, respectively, and the erase operation is performed on Bit2 through DHE (drain hot-electron injection) when the logic variables B and C are 0 and 1, respectively.

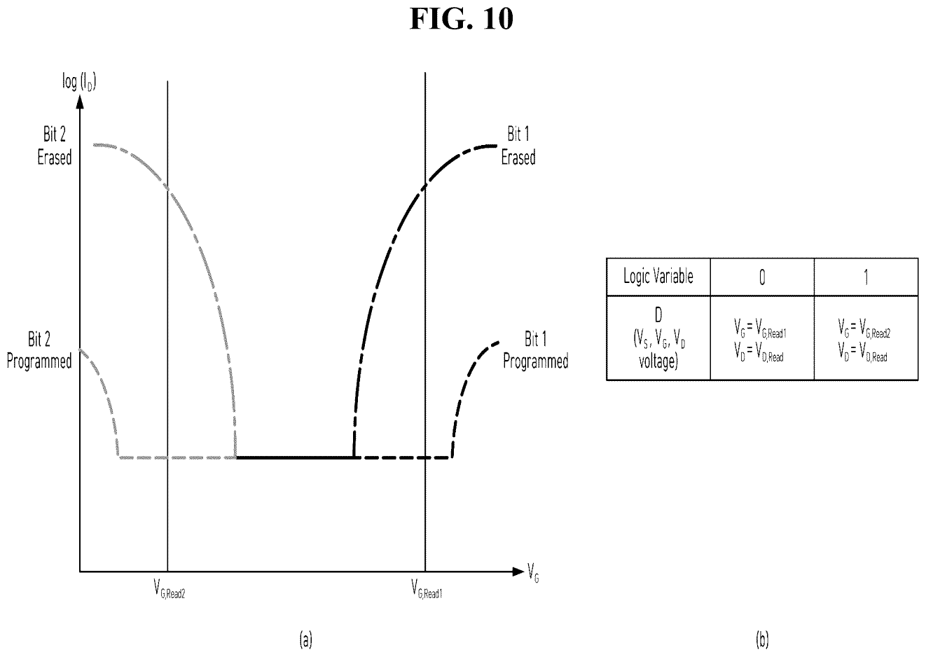

FIG. 10 illustrates the Read step, which is step 3 of the Boolean logic operation, in which FIG. 10(a) shows the gate voltage applied according to the value of a logic variable D and the drain current-gate voltage relationship for each case, and FIG. 10(b) shows the bias state according to the value of the logic variable D.

Step 3 performs the read operation on the result of the Boolean logic operation. Step 3 performs the read operation of the first charge storage layer or the second charge storage layer by adjusting the voltage level of the gate voltage V_{G}. In step 3, the result of the Boolean logic operation may be determined by comparing a current level during the read operation with the reference level. Step 3 is the final step of the Boolean logic operation, and reads the result value of the Boolean logic operation. In step 3, V_{G,read1} is applied as the gate voltage V_{G} to read information on Bit1 when the logic variable D is 0, and V_{G,read2} is applied as the gate voltage V_{G} to read information on Bit2 when the logic variable D is 1. In step 3, if the current value during the read operation is above a certain level, the result value of the Boolean logic operation is determined to be 1. If the current value during the read operation is below a certain level, the result value of the Boolean logic operation is determined to be 0. Here, current means drain current I_{D}.

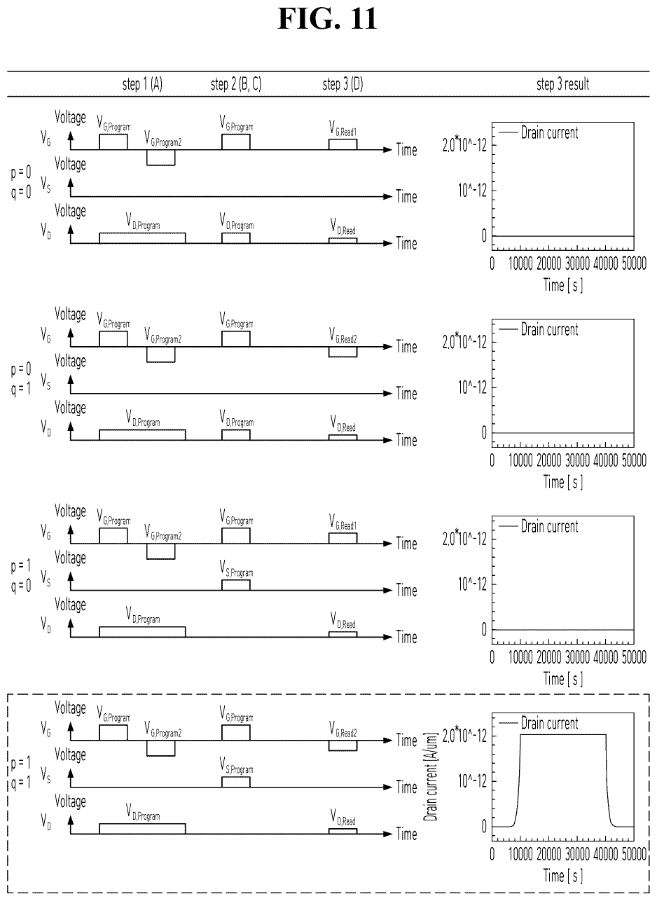

FIG. 11 is a graph showing the simulation result of AND operation. It shows a conceptual diagram of pulses that are to be applied to the source, gate, and drain stages for AND operation and verification results of AND operation through TCAD.

Referring to FIG. 11, in order to perform the AND operation, the logic variable values were set to A=0, B=0, C=p, and D=q, respectively. The result of step 3 is a value obtained by calculating p AND q, and it can be confirmed that a high value of drain current flows only when both p and q are 1. If it is defined as 1 when high drain current flows and it is defined as 0 when low drain current flows, it can be confirmed that p AND q operation was performed well.

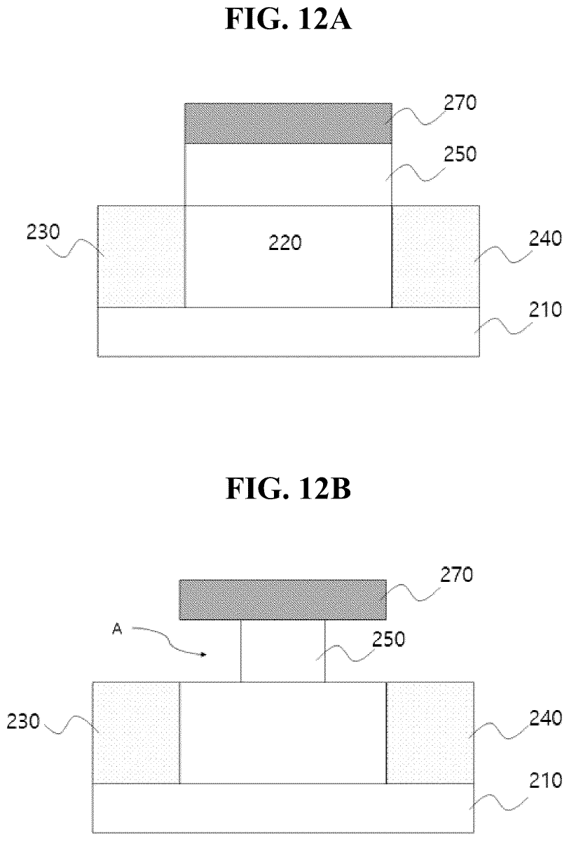

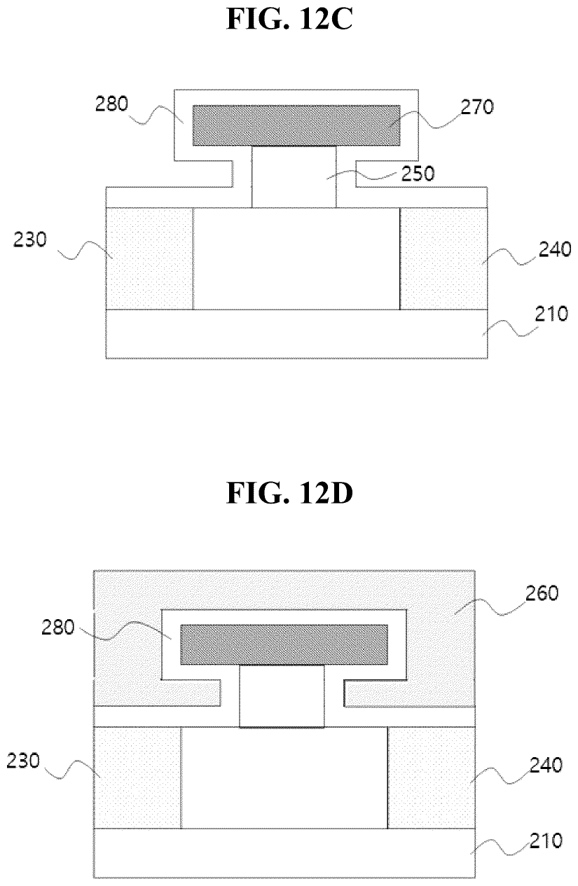

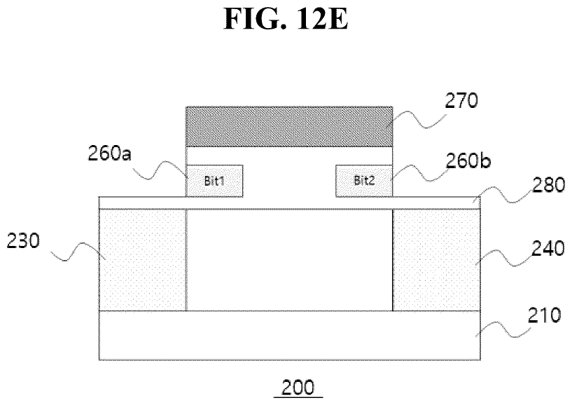

FIGS. 12A to 12E are diagrams illustrating a method of manufacturing a charge storage type tunneling transistor device according to an embodiment of the present disclosure.

Referring to FIGS. 12A to 12E, the method of manufacturing the charge storage type tunneling transistor device according to the present disclosure will be sequentially described as follows.

First, referring to FIG. 12A, a dielectric layer 250 and a gate layer 270 are formed over a semiconductor substrate 210.

The semiconductor substrate 210 may be formed of a Silicon On Insulator (SOI) substrate or a silicon substrate. The semiconductor substrate 210 may be formed of Buried Oxide (BOX) at the bottom of the SOI and a silicon substrate. Here, the SOI corresponds to a substrate of a structure with an insulating layer formed between silicon single crystal layers. The buried oxide is an oxide layer used as an insulating film, not only serves as an electrical insulator but also corresponds to oxide used to isolate devices in the process of manufacturing an integrated circuit, and serves as a diffusion barrier for regions other than a specific region in the process of doping impurities into the specific region on the SOI. Hereinafter, the semiconductor substrate 210 is not necessarily limited thereto.

The dielectric layer 250 may be formed of a first dielectric constant dielectric film material or a second dielectric constant dielectric film material. Here, a first dielectric constant dielectric film may correspond to a low dielectric constant (Low-k) film with a lower dielectric constant than a second dielectric constant dielectric film, while the second dielectric constant dielectric film may correspond to a high dielectric constant (High-k) film. The first dielectric constant dielectric film material may include one of silicon oxide (SiO₂) and silicon oxynitride (SiON). The second dielectric constant dielectric film material may include one of strontium oxide (SrO), aluminum oxide (Al₂O₃), magnesium oxide (MgO), scandium oxide (Sc₂O₃), gadolinum oxide (Gd₂O₃), yttrium oxide (Y₂O₃), samarium oxide (Sm₂O₃), hafnium oxide (HfO₂), zirconium oxide (ZrO₂), titanium oxide (TiO₂), tantalum oxide (Ta₂O₅), barium oxide (BaO), and bismuth oxide (Bi₂O₃).

The gate layer 270 may be formed of a silicon-based material such as polysilicon or amorphous silicon or a metal material. Here, an n+ polysilicon layer is used, but the present disclosure is not necessarily limited thereto.

Subsequently, the gate layer 270 and the dielectric layer 250 are etched to form a gate pattern with a certain line width.

After forming a gate pattern, the source region 230 and the drain region 240 are formed in the semiconductor substrate 210 using the pattern as a mask. The source region 230 and the drain region 240 may be formed by doping impurities through a diffusion process or an Ion Implantation process. In an embodiment, the source region 230 may be formed as a P+ region, and the drain region 240 may be formed as an N+ region. The channel region 220 may be lightly doped (P−) with P-type impurities compared to the source region 230, or may be formed as an undoped intrinsic region. This may be lightly doped (N− region) with N-type impurities compared to the drain region 240, or may be formed as an undoped intrinsic region.

Thereafter, referring to FIG. 12B, the side of the dielectric layer 250 with the gate pattern is further etched to have a line width narrower than that of the gate layer 270. That is, an undercut-shaped space like ‘A’ is formed on both sides of the bottom of the gate pattern. At this time, the etching process of the dielectric layer 250 may be performed using normal dry or wet etching. When the dielectric layer 250 is formed of silicon oxide SiO₂, an HF vapor etch process may be performed using hydrofluoric acid gas.

Then, referring to FIG. 12C, an oxide film 280 is formed on the entire surface including the etched dielectric layer 250 through an oxidation process. Here, the oxide film 280 may be formed of the same material as the dielectric layer 250 to secondarily form the dielectric layer 250 on the source region 230 and the drain region 240.

Thereafter, referring to FIG. 12D, a charge storage layer 260 is formed along the entire surface including the gate pattern on which the oxide film 280 is formed. At this time, the charge storage layer 260 may be formed to completely fill the space A created by the etched dielectric layer 250. Here, the charge storage layer 260 may be formed using materials with high silicon process compatibility. For example, the charge storage layer 260 may be formed of a semiconductor material such as polysilicon or a material such as Si₃N₄, HfO₂, or Al₂O₃.

Finally, referring to FIG. 12E, the oxide film 280 and the charge storage layer 260 are etched using the gate layer 270 on the top of the gate pattern as an etch mask to form the first and second charge storage layers 260a and 260b on both sides of the dielectric layer 250 with the gate pattern. In this regard, the first and second charge storage layers 260a and 260b may independently store charges through the selective program or erase operation.

As described above, a charge storage type tunneling transistor device according to the present disclosure forms first and second charge storage layers that independently store charges on both sides of a gate pattern, and adjusts voltage levels of a threshold voltage Vₜₕ and an ambipolar voltage V_{amb} of the device, thereby performing the selective program or erase operation on the first and second charge storage layers. Therefore, the present disclosure is advantageous in terms of low power operation compared to a metal-oxide-semiconductor field effect transistor (MOSFET), because it uses a tunneling transistor with low power/high energy efficiency. This provides superior effect in implementing an energy-saving semiconductor system that requires low leakage current and operating voltage. Further, when performing the Boolean logic operation through the charge storage type tunneling transistor device of the present disclosure, data movement between a processing unit and a memory unit is dramatically reduced, thereby reducing time and energy consumption. These advantages from the energy point of view can be further applied to a system semiconductor used in a portable electronic device that should perform operation with low power.

Although the present disclosure has been described above with reference to preferred embodiments, it will understood by those skilled in the art that various modifications and changes may be made to the present disclosure without departing from the idea and scope of the present disclosure as set forth in the following claims.

### DESCRIPTION OF REFERENCE NUMERALS

| | |
|---|---|
| 100, 200: charge storage type | |
| tunneling transistor device | |
| 110, 210: semiconductor substrate | 120, 220: channel region |
| 130, 230: source region | 140, 240: drain region |
| 150, 250: dielectric layer | |
| 160a, 160b, 260, 260a, 260b: | |
| charge storage layer | |
| 170, 270: gate | 280: oxide film |

1. A charge storage type tunneling transistor device comprising:
a semiconductor substrate;
a gate formed on the semiconductor substrate;
a source region and a drain region spaced apart from each other via a channel region that is formed under the gate;
a dielectric layer formed between the gate and the channel region; and
first and second charge storage layers buried in the dielectric layer to be spaced apart from each other, and independently storing charge.

2. The device of claim 1, wherein the dielectric layer is primarily formed between the gate and the channel region, and at least portion thereof overlaps the channel region.

3. The device of claim 2, wherein the dielectric layer is secondarily formed on the source region and the drain region.

4. The device of claim 1, wherein the dielectric layer is formed of a first dielectric constant dielectric film material or a second dielectric constant dielectric film material having different dielectric constants.

5. The device of claim 4, wherein the first dielectric constant dielectric film material includes one of silicon oxide (SiO₂) and silicon oxynitride (SiON).

6. The device of claim 4, wherein the second dielectric constant dielectric film material includes one of strontium oxide (SrO), aluminum oxide (Al₂O₃), magnesium oxide (MgO), scandium oxide (Sc₂O₃), gadolinum oxide (Gd₂O₃), yttrium oxide (Y₂O₃), samarium oxide (Sm₂O₃), hafnium oxide (HfO₂), zirconium oxide (ZrO₂), titanium oxide (TiO₂), tantalum oxide (Ta₂O₅), barium oxide (BaO), and bismuth oxide (Bi₂O₃).

7. The device of claim 1, wherein the first and second charge storage layers independently or simultaneously control the storage of the charge through selective program or erase operation.

8. The device of claim 7, wherein the first and second charge storage layers selectively or simultaneously perform the program or erase operation by adjusting a threshold voltage (Vₜₕ) that is a gate voltage when a tunneling current above a certain level flows between the source region and the channel region or an ambipolar voltage (V_{amb}) that is a gate voltage when a tunneling current above a certain level flows between the drain region and the channel region.

9. The device of claim 1, wherein the first and second charge storage layers are formed of a hetero gate dielectric, and are made of the same material.

10. The device of claim 9, wherein the first and second charge storage layers are formed of polysilicon or a material selected from Si₃N₄, HfO₂, Al₂O₃, and combinations thereof.

11. The device of claim 1, wherein the first and second charge storage layers are formed on top of the secondarily formed dielectric layer in the source region and the drain region, respectively.

12. A method of manufacturing a charge storage type tunneling transistor device comprising:
forming a dielectric layer and a gate layer over a semiconductor substrate;
forming a source region, a drain region, and a channel region within the semiconductor substrate;
forming an undercut-shaped space on both sides on a bottom of the gate layer by etching both sides of the dielectric layer;
forming an oxide film on an entire surface including the dielectric layer through an oxidation process, and forming a charge storage layer along the entire surface to fill the space; and
forming first and second charge storage layers buried in the dielectric layer to be spaced apart from each other by etching the oxide film and the charge storage layer.

13. The method of claim 12, wherein the dielectric layer is formed of silicon oxide (SiO₂), and the space is created by performing an HF vapor etch process.

14. The method of claim 12, wherein the first and second charge storage layers independently store charge by selectively or simultaneously performing program and erase operations.

15. A Boolean logic operation method of a charge storage type tunneling transistor device, the method comprising:
step 1 of setting first and second charge storage layers to an initial state, the first and second charge storage layers being buried in a dielectric layer formed between a gate and a channel region to be spaced apart from each other and independently storing charge;
step 2 of performing a Boolean logic operation by performing selective program or erase operation; and
step 3 of performing a read operation on a result of the Boolean logic operation.

16. The method of claim 15, wherein the step 1 initializes the threshold voltage (Vₜₕ) and ambipolar voltage (V_{amb}) to an arbitrary value.

17. The method of claim 15, wherein the step 2 comprises:
adjusting a voltage level of the threshold voltage (Vₜₕ) by performing program or erase operation of the first charge storage layer; and
adjusting a voltage level of the ambipolar voltage (V_{amb}) by performing program and erase operation of the second charge storage layer,
wherein the voltage level adjustment of the threshold voltage (Vₜₕ) and the voltage level adjustment of the ambipolar voltage (V_{amb}) are independently performed.

18. The method of claim 15, wherein the step 2 comprises:
performing program or erase operation on the first charge storage layer through BBHE (Band-to-band tunneling induced hot-electron injection) or FN (Fowler Nordheim) tunneling.

19. The method of claim 15, wherein the step 2 comprises:
performing program or erase operation on the second charge storage layer through BBHH (Band-to-band tunneling induced hot-hole injection) or DHE (drain hot-electron injection).

20. The method of claim 15, wherein the step 3 comprises:
performing read operation of the first charge storage layer or the second charge storage layer by adjusting a voltage level of gate voltage (V_{G}); and
comparing a current level of drain current (I_{D}) during the read operation with a reference level to determine a result of the Boolean logic operation.
